(19) United States
(12) Patent Application Publication
(10) Pub. No.: US 2025/0014980 A1
(43) Pub. Date: Jan. 9, 2025

(54) INTERLINKED GROUND WELLS WITH SPECIALIZED PATTERNS FOR LIQUID METAL INTERPOSER

(71) Applicant: Intel Corporation, Santa Clara, CA (US)

(72) Inventors: Eric ERIKE, Mesa, AZ (US); Anikki GIESSLER, Tempe, AZ (US); Zhichao ZHANG, Chandler, AZ (US); Srikant NEKKANTY, Chandler, AZ (US); Saikat MONDAL, Chandler, AZ (US)

(21) Appl. No.: 18/219,018

(22) Filed: Jul. 6, 2023

(51) Int. Cl. H01L 23/498; H01R 12/52

(52) U.S. Cl. CPC H01L 23/49838; H01L 23/49833; H01L 23/49866; H01R 12/52; H01L 23/5385; H05K 1/18; H05K 2201/10318; H05K 2201/10378

(57) ABSTRACT

Embodiments disclosed herein include a liquid metal interposer. In an embodiment, the liquid metal interposer comprises a substrate with a first opening in the substrate and a second opening in the substrate. In an embodiment, a channel is between the first opening and the second opening. In an embodiment, the channel fluidically couples the first opening to the second opening.

### TECHNICAL FIELD

Embodiments of the present disclosure relate to electronic systems, and more particularly, to liquid metal interposers that include interlinked ground wells.

### BACKGROUND

As electronic packages continue to scale and the number of interconnects increases, traditional socketing architectures are reaching their feasible limits. In the case of a land grid array (LGA) socket architecture, the force needed to connect the pins to the package is quickly exceeding assembly capabilities. Accordingly, alternative socketing architectures are needed. One potential solution includes the use of liquid metal. In such architectures, a liquid metal interposer array that includes a plurality of wells is attached to the bottom side of the package substrate. The wells are filled with a liquid metal, such as a material composition comprising gallium. In some instances a capping layer is provided over the wells to confine the liquid metal to the wells. Pins from the board are then inserted through the capping layer in order to make direct contact with the liquid metal.

Liquid metal architectures are promising, but existing solutions are still subject to significant limitations. For example, the wells that are formed in the liquid metal interposer are formed with a drilling process. Tolerances in the drilling process lead to variations in the well diameters. This leads to non-uniform liquid metal volumes, which can negatively impact signal propagation between the board and the package substrate. Drilling processes also result in rough sidewall surfaces, which is not desirable. Further, circular wells are generally the only shape that can be formed with a drilling process. This limits the flexibility in optimizing electrical performance of the liquid metal solution. Physical drilling processes are also limited by a relatively large well diameter. As scaling continues, drilling may not be feasible for fine pitch and small diameter pins.

In addition to limitations in design flexibility, currently available liquid metal solutions are extremely high cost solutions. This is because each well needs to be individually drilled. Small form factors with a limited number of wells may be feasible. However, as scaling and pin count continue to increase (e.g., 1,000 or more pins, 4,000 or more pins, etc.), drilling each well becomes a show stopper.

### BRIEF DESCRIPTION OF THE DRAWINGS

FIG. 1A is a cross-sectional illustration of a liquid metal interposer before formation of the openings.

FIG. 1B is a cross-sectional illustration of the liquid metal interposer during physical drilling of the openings.

FIG. 1C is a plan view illustration of the liquid metal interposer after the openings are drilled.

FIG. 2A is a cross-sectional illustration of a liquid metal interposer that is formed with an injection molding process, in accordance with an embodiment.

FIG. 2B is a plan view illustration of a liquid metal interposer with circular openings, in accordance with an embodiment.

FIG. 2C is a plan view illustration of a liquid metal interposer with polygonal openings, in accordance with an embodiment.

FIG. 2D is a plan view illustration of a liquid metal interposer with square openings, in accordance with an embodiment.

FIG. 3A is a perspective view of a hole that is a cylindrical shape, in accordance with an embodiment.

FIG. 3B is a perspective view of a hole with a first shape at a top and a second shape at a bottom, in accordance with an embodiment.

FIG. 3C is a perspective view of a hole with an hourglass shape, in accordance with an embodiment.

FIG. 3D is a perspective view of a hole with a tapered shape, in accordance with an embodiment.

FIG. 4A is a cross-sectional illustration of a portion of a liquid metal interposer with a first opening, a second opening, and a channel coupling the first opening to the second opening, in accordance with an embodiment.

FIG. 4B is a cross-sectional illustration of a portion of a liquid metal interposer with a first opening, a second opening, and an embedded channel coupling the first opening to the second opening, in accordance with an embodiment.

FIG. 4C is a cross-sectional illustration of a portion of a liquid metal interposer with a first opening, a second opening, and embedded channels coupling the first opening to the second opening, in accordance with an embodiment.

FIG. 5A is a cross-sectional illustration of a lower portion of a liquid metal interposer, in accordance with an embodiment.

FIG. 5B is a cross-sectional illustration of an upper portion of a liquid metal interposer being attached to a lower portion of the liquid metal interposer to enable formation of an embedded channel, in accordance with an embodiment.

FIG. 6A is a plan view illustration of a liquid metal interposer with signal openings and ground openings, where there is no coupling between openings.

FIG. 6B is a plan view illustration of a liquid metal interposer with signal openings and ground openings, where ground openings are coupled together by channels, in accordance with an embodiment.

FIG. 6C is a plan view illustration of a liquid metal interposer with signal openings that are surrounded by ground openings that are coupled together by channels, in accordance with an embodiment.

FIG. 7 is a graph of the available frequencies for liquid metal interposers shown in FIGS. 6A-6C, in accordance with an embodiment.

FIG. 8 is a cross-sectional illustration of an electronic system that includes an injection molded liquid metal interposer with embedded channels between openings, in accordance with an embodiment.

FIG. 9 is a schematic of a computing device built in accordance with an embodiment.

### EMBODIMENTS OF THE PRESENT DISCLOSURE

Described herein are electronic systems, and more particularly, substrates or interposers that include interlinked ground wells having liquid metal, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

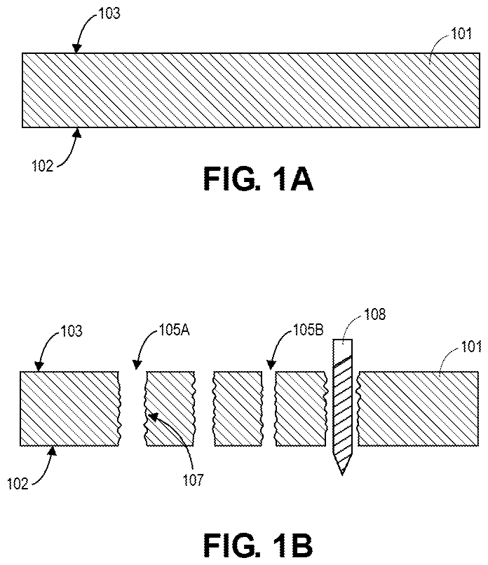

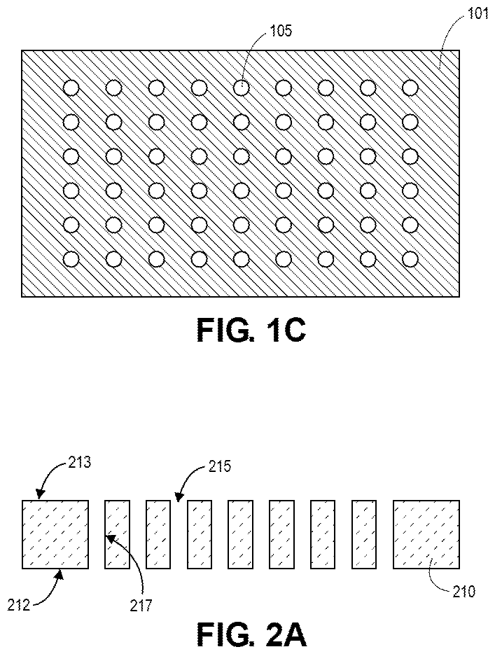

In order to provide context for embodiments disclosed herein, FIGS. 1A-1C are illustrations depicting a traditional liquid metal interposer 101. Referring now to FIG. 1A, a cross-sectional illustration of a liquid metal interposer 101 before the openings are formed is shown. The liquid metal interposer 101 may be an electrically insulating material. More particularly, existing liquid metal interposers 101 need to have a material composition that is compatible with mechanical drilling (e.g., mechanical stress and thermal stress). In one instance, an organic material that is reinforced with fibers, such as glass fibers, may be used. The thickness of the liquid metal interposer 101 may be approximately 100 μm or more. In a particular instance, the thickness of the liquid metal interposer 101 may be between approximately 300 μm and approximately 700 μm. As used herein, “approximately” refers to a range of values within ten percent of the stated value. For example, approximately 100 μm may refer to a range between 90 μm and 110 μm.

Referring now to FIG. 1B, a cross-sectional illustration of the liquid metal interposer 101 during formation of openings 105 is shown. The openings 105 may be formed with a mechanical drilling process. For example, drill 108 passes through the liquid metal interposer 101 to form the openings 105. Due to processing tolerances inherent in mechanical drilling processes, the diameter of the openings may be non-uniform. For example, opening 105A is wider than opening 105B. Variations in opening diameter results in non-uniform liquid metal volumes in each opening. This can lead to issues with electrical performance.

Further, the use of mechanical drilling results in rough sidewall surfaces 107. The sidewall surfaces 107 may have an average roughness Ra that is greater than an average surface roughness Ra of either the top surface 103 or the bottom surface 102. The rough surfaces of the sidewalls 107 may also negatively impact electrical performance of the liquid metal interposer 101.

The use of mechanical drilling is also limited with respect to the shape of the openings 105. Generally, the openings 105 can only be roughly cylindrical shapes. That is, the shape of the openings 105 at the top surface 103 and the bottom surface 102 may be circular, and the sidewalls 107 may be generally vertical. Accordingly, flexibility to modify electrical performance by modifying liquid metal volume is limited.

Referring now to FIG. 1C, a plan view illustration of the completed liquid metal interposer 101 is shown. The liquid metal interposer 101 may comprise an array of openings 105. While shown as being substantially uniform in FIG. 1C, it is to be appreciated that machining tolerances will result in opening 105 diameters being non-uniform, and the placement of the openings 105 may not be perfectly arranged in an ordered array.

The mechanical drilling process may also lead to damage to the liquid metal interposer 101. For example, excess heat provided by the drilling process may negatively impact the structure of the liquid metal interposer 101. Mechanical drilling is also a time consuming process and is expensive. This leads to small form factors for the liquid metal interposer 101. For example, existing mechanical drilling processes may be limited to form factors of approximately 35 mm by approximately 50 mm or smaller. As such, existing liquid metal interposers 101 are not compatible with many advanced packaging solutions that require thousands (e.g., 1,000 or more, or 4,000 or more) pins.

Further, it is to be appreciated that the openings 105 are not able to be stitched or otherwise coupled together. As such, electrical performance is limited. More particularly, it may be desirable to stitch together ground interconnects in order to improve cross-talk reduction. Reducing cross-talk can lead to improvements in operating frequency, which directly correlates to increased data rates on the signaling interconnects. However, due to the vertical drilling limitations, lateral channels or other lateral interconnects between openings 105 are not possible.

Accordingly, embodiments disclosed herein include liquid metal interposers that are formed with an alternative process. More particularly, embodiments include liquid metal interposers that are formed with a molding process, such as an injection molding process. The use of an injection molding process has significant benefits compared to physical drilling. For one, the dimensional control of the openings is improved, which leads to highly uniform liquid metal volumes in each opening. The surface roughness of sidewalls of the openings may also be improved. For example, a surface roughness of the sidewalls of the openings may be substantially equal to the surface roughness of the top and bottom surface of the liquid metal interposer. As used herein, liquid metal interposers may be referred to simply as “interposers”. Alternative naming conventions may refer to liquid metal interposers as “liquid metal carriers” in some instances as well.

Molding processes also enable far greater degrees of design flexibility. For example, the shape of the openings may be circular, square, or any polygonal shape. The shape at the top of the opening may also be different than a shape at the bottom of the opening. Also, openings with different shapes may be formed on a single liquid metal interposer. Molding processes may also allow for sidewalls to be non-vertical. In one instance, the sidewalls may be tapered. In another instance, the sidewalls may have an hourglass shaped profile (i.e., wide at the top and bottom and narrow at the middle).

Molding processes can also be used to form complex opening shapes. For example, an opening may include one or more channels that extend laterally away from the sidewall of the opening. Further, channels may be formed that allow for fluidically coupling together two or more openings. Such embodiments may be enabled through the use of a multi-layered liquid metal interposer.

In addition to design flexibility, molded liquid metal interposers provide improved scaling, while also significantly reducing costs. Since a single molding process is used to form all of the openings substantially in parallel, large form factors (e.g., approximately 150 mm by approximately 150 mm or larger) can be fabricated. The dimensions of the openings are also easier to scale to smaller dimensions. As such, pin counts of approximately 1,000 or more, or approximately 4,000 or more can be cost effectively manufactured. Compared to mechanical drilling processes, injection molding solutions can be one or two (or more) orders of magnitude less expensive.

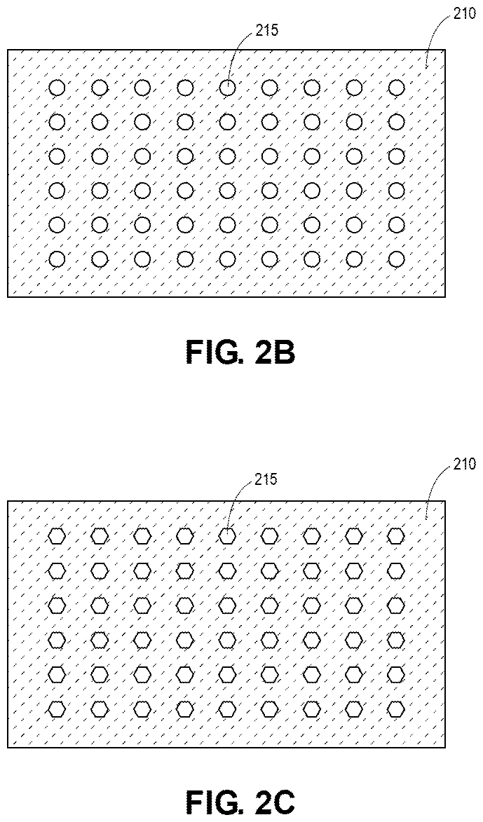

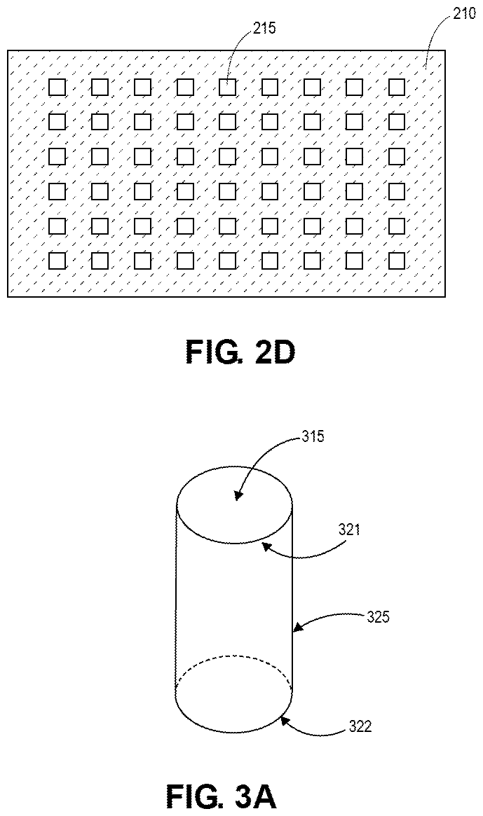

Referring now to FIG. 2A, a cross-sectional illustration of a liquid metal interposer 210 is shown, in accordance with an embodiment. The liquid metal interposer 210 may be formed with a molding process. More particularly, the liquid metal interposer 210 may be formed with an injection molding process. The material composition of the liquid metal interposer 210 may be any suitable polymer that is compatible with injection molding processes. For example, the liquid metal interposer 210 may comprise a polymer, such as, but not limited to, polyvinyl chloride (PVC), polypropylene (PP), polyethylene terephthalate (PET), polymethyl methacrylate (PMMA), high density polyethylene (HDPE), low density polyethylene (LDPE), acrylonitrile butadiene styrene (ABS), styrene acrylonitrile (SAN), or polystyrene.

In an embodiment, the liquid metal interposer 210 may be any suitable thickness. For example, the liquid metal interposer 210 may be approximately 50 μm or thicker, or approximately 100 μm or thicker. In one instance, the liquid metal interposer 210 may have a thickness between approximately 300 μm and approximately 700 μm. In an embodiment, the liquid metal interposer 210 may have any desired form factor. For example, the length and width of the liquid metal interposer 210 may be approximately 150 mm by approximately 150 mm. Though, smaller or larger form factors may also be used in some embodiments.

In an embodiment, a plurality of openings 215 may be provided through a thickness of the liquid metal interposer 210. In some instances, the openings 215 may be referred to as wells. Injection molding processes allow for a high degree of uniformity between each of the openings 215. For example, in instances where the opening diameter of two openings 215 are intended to be the same, the true difference between the diameter of the two openings 215 may be approximately 1 μm or less, approximately 0.5 μm or less, approximately 0.1 μm or less, or approximately 0.01 μm or less.

In an embodiment, the openings 215 may have substantially vertical sidewalls 217. Though, as will be described in greater detail below, the sidewalls 217 may not be vertical in some embodiments. The injection molding process can result in sidewalls that have a smooth surface. For example, the sidewalls 217 may have an average surface roughness Ra that is substantially equal to the average surface roughness Ra of either the top surface 213 or the bottom surface 212. As used herein, substantially equal average surface roughnesses may refer to surface roughnesses that are within ten percent of each other. In a particular embodiment, the average surface roughness Ra of the sidewalls 217 may be approximately 1 μm or less, approximately 0.1 μm or less, or approximately 0.01 μm or less.

Referring now to FIG. 2B, a plan view illustration of the liquid metal interposer 210 is shown, in accordance with an embodiment. The liquid metal interposer 210 may have an array of openings 215 provided across the surface of the liquid metal interposer 210. While shown as being in a grid array (e.g., a 9×6 grid is shown in FIG. 2B), it is to be appreciated that the openings 215 may be provided with any desired layout. For example, the pitch between each of the openings 215 may be non-uniform in some embodiments.

In an embodiment, the openings 215 are shown as having a circular shape. For example, the openings 215 may have a cylindrical three dimensional shape through the thickness of the liquid metal interposer 210. In the illustrated embodiment, each of the openings 215 have the same diameter. Though, in other embodiments, openings 215 with different diameters may be provided on a single liquid metal interposer 210. In an embodiment, the diameter of the openings 215 may be approximately 50 μm or less, approximately 10 μm or less, or approximately 5 μm or less. Accordingly, aggressive scaling can be enabled using injection molding processes.

Referring now to FIG. 2C, a plan view illustration of a liquid metal interposer 210 is shown, in accordance with yet another embodiment. Instead of being limited to just circular openings 215, it is to be appreciated that non-circular openings may also be used. For example, the openings 215 in FIG. 2C are hexagonal openings. Referring now to FIG. 2D, the openings 215 are square shaped. More generally, the openings 215 may have any polygonal shape, an oval shape, a circular shape, or any irregular shape.

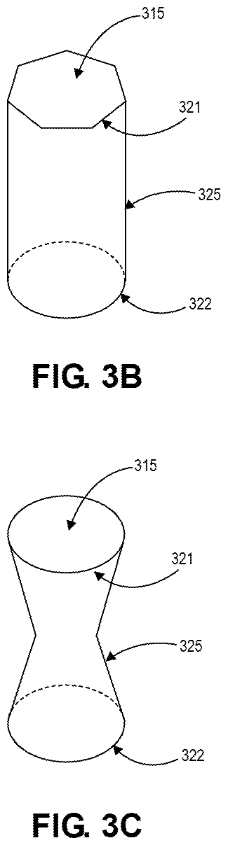

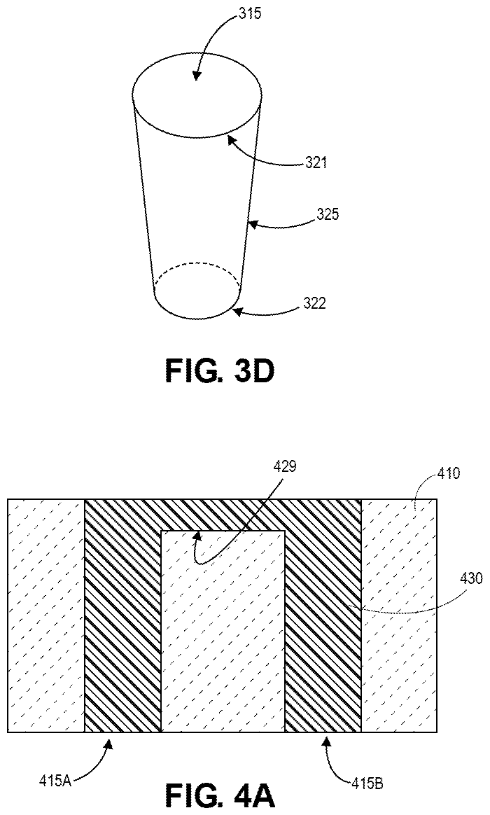

Referring now to FIGS. 3A-3D, examples of various opening 315 shapes are shown, in accordance with various embodiments. In FIGS. 3A-3D, the liquid metal interposer is omitted for clarity. It is to be appreciated that the sidewalls of the openings 315 in FIGS. 3A-3D will be surrounded by an injection molded polymer, such as those described in greater detail above.

Referring now to FIG. 3A, an illustration of an opening 315 is shown, in accordance with an embodiment. The opening 315 may include a first shape 321 at a top surface and a second shape 322 at a bottom surface. The first shape 321 and the second shape 322 may be the same shape and the same size. For example, in FIG. 3A, the first shape 321 and the second shape 322 are both circles with the same diameter.

Accordingly, a sidewall 325 of the opening 315 is substantially vertical in order to couple the first shape 321 to the second shape 322. While a circle shape is shown in FIG. 3A, it is to be appreciated that any shape may be used for both the first shape 321 and the second shape 322.

Referring now to FIG. 3B, an illustration of an opening 315 is shown, in accordance with an additional embodiment. The opening 315 may include a first shape 321 at a top surface and a second shape 322 at a bottom surface. In an embodiment, the first shape 321 may be different than the second shape 322. For example, the first shape 321 may be a hexagon, and the second shape 322 may be a circle. The sidewall 325 may be substantially vertical as well. It is to be appreciated that any two shapes may be combined to form the opening 315. For example, a square and a circle may be combined, a square and a hexagon may be combined, or any other suitable shape combination may be used.

Referring now to FIG. 3C, an illustration of an opening 315 is shown, in accordance with an additional embodiment. The opening 315 may include a first shape 321 at a top surface and a second shape 322 at a bottom surface. In an embodiment, the sidewall 325 between the first shape 321 and the second shape 322 may be non-vertical. For example, the sidewall 325 may have a double tapered profile. Such an embodiment may be referred to as being hourglass shaped. An hourglass shape may include a shape that has top and bottom dimensions that are wider than a dimension at a point between the top and bottom surface.

In the illustrated embodiment, the opening 315 has a circular first shape 321 and a circular second shape 322. It is to be appreciated that similar hourglass shapes can be formed with any shapes for the first shape 321 and the second shape 322. In some instances the first shape 321 may be different than the second shape 322, while still having an hourglass shape.

Referring now to FIG. 3D, an illustration of an opening 315 is shown, in accordance with an additional embodiment. The opening 315 may include a first shape 321 at a top surface and a second shape 322 at a bottom surface. In an embodiment, the first shape 321 may be a different size than the second shape 322. For example, the second shape 322 may be smaller than the first shape 321. In such an embodiment, the sidewall 325 may be non-vertical. Such an opening 315 may be referred to as having a tapered shape. While both the first shape 321 and the second shape 322 are shown as circles, it is to be appreciated that a tapered opening 315 may be formed with any shape, or any combination of shapes.

In addition to flexibility in the shape and size of openings, it is to be appreciated that injection molding processes also allow for more complex opening architectures. For example, some embodiments may include lateral channels that couple together neighboring openings. Such coupled openings provide improved design flexibility in order to fabricate improved signaling architectures. As will be described in greater detail below, coupled ground interconnects may be used in order to decrease cross-talk, increase operating frequency, and increase data rates.

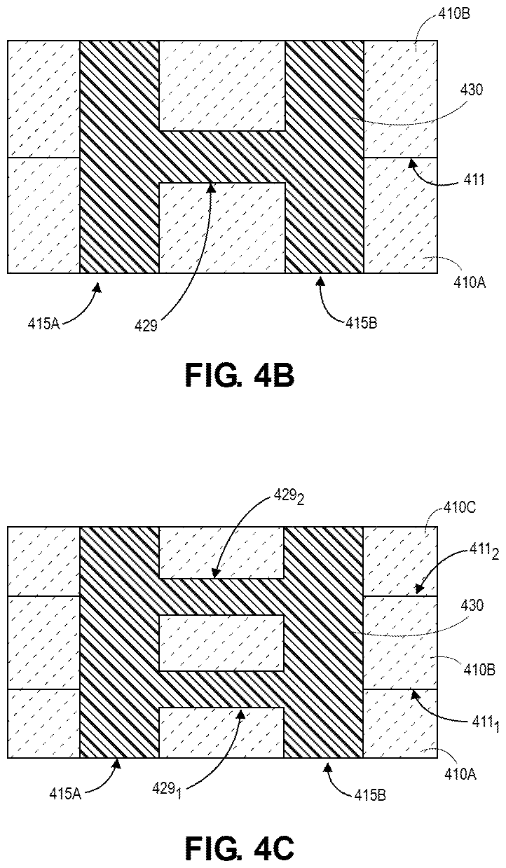

Referring now to FIG. 4A, a cross-sectional illustration of a portion of a liquid metal interposer 410 is shown, in accordance with an embodiment. The liquid metal interposer 410 may include a first opening 415A and a second opening 415B. The first opening 415A and the second opening 415B may be similar to each other. Though, first opening 415A may have a different shape, size, etc. than the second opening 415B. The openings 415A and 415B may have structures similar to any of the opening structures described in greater detail above.

In an embodiment, the first opening 415A may be coupled to the second opening 415B by a channel 429. The channel 429 may fluidically couple the two openings 415A and 415B together. For example, a liquid metal 430 may flow along the channel 429 between the first opening 415A and the second opening 415B. Fluidically coupled components refer to two components where, a fluid (e.g., liquid, gas, etc.) can flow from one component to the other component. As used herein, a liquid metal 430 refers to a material composition that is an electrically conductive metal that is liquid at (or around) room temperature. In some embodiments, a liquid metal 430 may remain a liquid down to 0 degrees Celsius. The liquid metal 430 may comprise gallium with (or without) any other alloying elements.

In the illustrated embodiment, the channel 429 is provided along the top surface of the liquid metal interposer 410. That is, the top surface of the channel 429 is open without an overlying portion of the liquid metal interposer 410. Of course, a similar channel 429 may be provided along the bottom surface of the liquid metal interposer 410. While not shown, it is to be appreciated that the liquid metal 430 may be confined by a capping layer or the like.

Referring now to FIG. 4B, a cross-sectional illustration of a portion of a liquid metal interposer 410 is shown, in accordance with an additional embodiment. In an embodiment, the liquid metal interposer 410 may be formed with a first portion 410A and an overlying second portion 410B. The first portion 410A may contact the second portion 410B at an interface 411. In some embodiments, an adhesive or other intervening layer may be provided at the interface 411 between the first portion 410A and the second portion 410B.

The use of a multi-layered approach allows for injection molding processes to form an embedded channel 429 between the first opening 415A and the second opening 415B. That is, portions of the liquid metal interposer 410 may be provided both above and below the channel 429. In an embodiment, the channel 429 may be at the same height within the liquid metal interposer 410 as the interface 411. In some instances, it may be said that the interface 411 intersects the channel 429.

Referring now to FIG. 4C, a cross-sectional illustration of a portion of a liquid metal interposer 410 is shown, in accordance with an additional embodiment. Instead of having a single channel 429 between the openings 415A and 415B, a plurality of channels 4291 and 4292 are provided between the openings 415A and 415B. The use of multiple channels 429 may improve the electrical coupling between the openings 415A and 415B and result in improved electrical performance.

In order to enable a second channel 4292, a third portion 410C of the liquid metal interposer 410 is provided. A first interface 4111 may be provided between the first portion 410A and the second portion 410B, and a second interface 4112 may be provided between the second portion 410B and the third portion 410C. The interface 4111 may intersect the first channel 4291, and the interface 4112 may intersect the second channel 4292.

While two channels 4291 and 4292 are shown in FIG. 4C, it is to be appreciated that any number of channels 429 may be provided between the first opening 415A and the second opening 415B. The number of layers of the liquid metal interposer 410 may be one more than the number of channels 429. For example, five channels 429 may be made when six layers are used to form the liquid metal interposer 410.

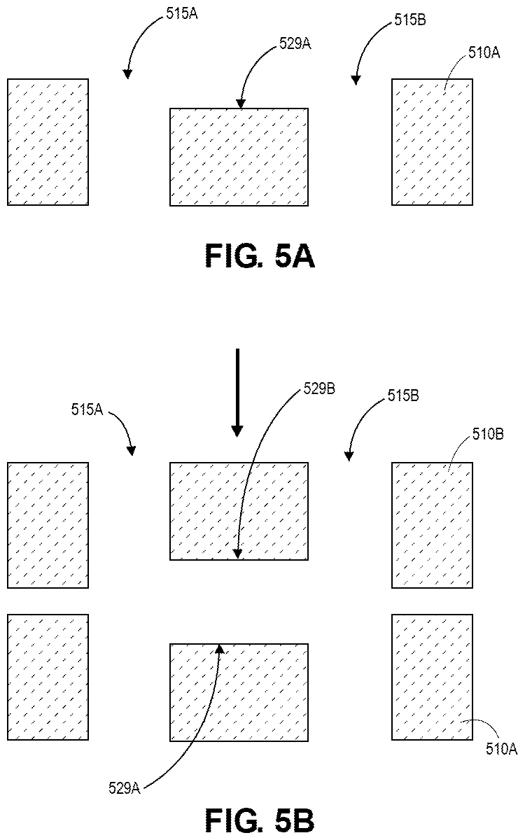

Referring now to FIGS. 5A and 5B, an illustration depicting the assembly process to form a liquid metal interposer with an embedded channel is shown, in accordance with an embodiment. In FIG. 5A, a first portion 510A of the liquid metal interposer 510 is shown. The first portion 510A may include a first opening 515A and a second opening 515B. The top surface of the first portion 510A between the first opening 515A and the second opening 515B may be recessed in order to form a first portion of the channel 529A.

Referring now to FIG. 5B, an illustration showing the attachment of a second portion of the liquid metal interposer 510B to the first portion of the liquid metal interposer 510A is shown, in accordance with an embodiment. As shown, the first portion 510A and the second portion 510B may be substantially similar to each other. For example, a second portion of the channel 529B may couple together the first opening 515A to the second opening 515B. Accordingly, bringing the two portions 510A and 510B together results in the formation of a channel between the first opening 515A and the second opening 515B that is formed from the first portion of the channel 529A and the second portion of the channel 529B.

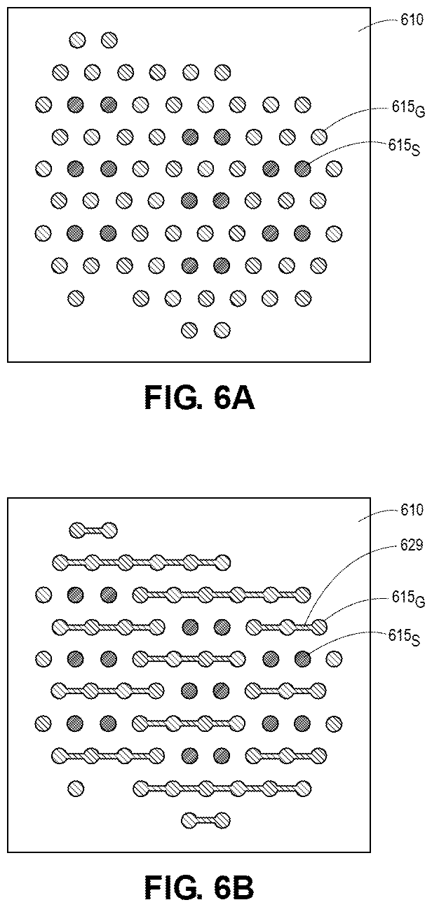

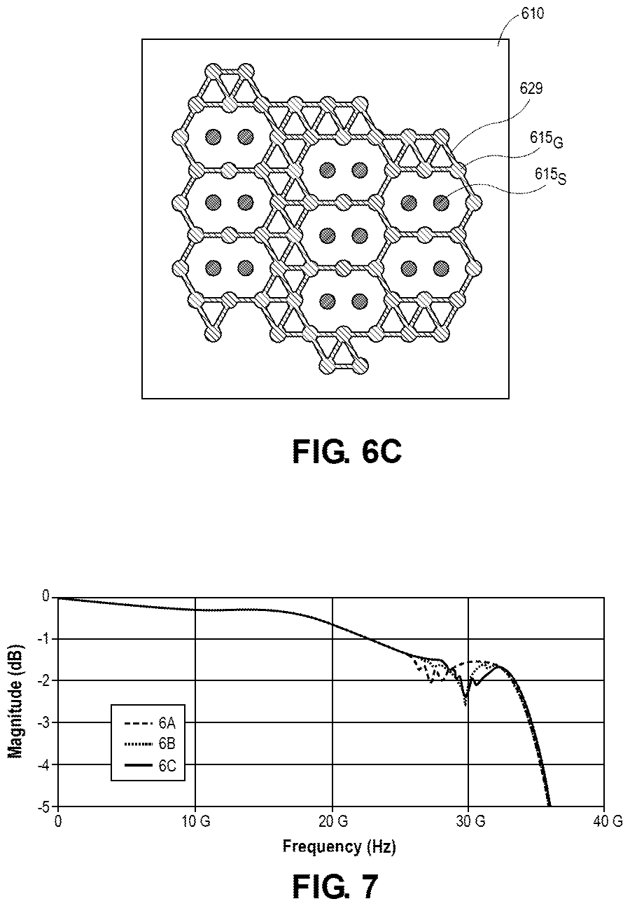

Referring now to FIGS. 6A-6C, plan view illustrations of liquid metal interposers that include ground interconnects and signal interconnects are shown. The embodiments shown in FIGS. 6A-6C provide an illustration for the advantages of coupling together two or more openings with channels.

Referring now to FIG. 6A, a plan view illustration of a liquid metal interposer 610 without lateral channels is shown, in accordance with an embodiment. As shown, signal interconnects 615_{S} may be surrounded by ground interconnects 615_{G}. Since the ground interconnects 615_{G} are not coupled to each other, the cross-talk between signal interconnects 615_{S} is not minimized, as will be shown in FIG. 7.

Referring now to FIG. 6B, a plan view illustration of a liquid metal interposer 610 with channels 629 is shown, in accordance with an embodiment. The channels 629 may electrically couple together ground interconnects 615_{G} within a row of the array. The channels 629 may couple together two or more ground interconnects 615_{G} within a row. For example, a single ground interconnect 615_{G} may be coupled to two neighboring ground interconnects 615_{G}. In an embodiment, the channels 629 may be embedded channels 629, may include two or more stacked channels 629 between adjacent ground interconnects 615_{G}, or may be similar to any of the channel architectures described in greater detail herein.

Referring now to FIG. 6C, a plan view illustration of a liquid metal interposer 610 with channels 629 is shown, in accordance with an additional embodiment. The channels 629 may electrically couple together ground interconnects 615_{G} that surround pairs of signal interconnects 615s. Multiple channels 629 may couple a plurality of ground interconnects 615_{G} to a single ground interconnect 615_{G}. For example, a single ground interconnect 615_{G} may be coupled to three or more neighboring ground interconnects 615_{G}, or four or more neighboring ground interconnects 615_{G}. In an embodiment, the channels 629 may be embedded channels 629, may include two or more stacked channels 629 between adjacent ground interconnects 615_{G}, or may be similar to any of the channel architectures described in greater detail herein.

Referring now to FIG. 7, a graph of the operating frequency of the liquid metal interposers shown in FIGS. 6A-6C is shown, in accordance with an embodiment. As shown, the performance of all three architectures is substantially uniform up to approximately 24 GHz. At this point, the first liquid metal interposer 610 in FIG. 6A experiences significant interference. As such, the first liquid metal interposer 610 in FIG. 6A exhibits the lowest frequency. In contrast the maximum operating frequency is shifted right for the liquid metal interposers 610 in FIGS. 6B and 6C. For example, increases up to approximately 30 GHz are enabled by the improved grounding scheme enabled by the channels 629 between ground interconnects 615_{G}. The improvements in FIG. 6C may be slightly better than those obtained in FIG. 6B.

It is to be appreciated that increases in the operating frequency directly correlate to improvements in data rate transmission. For example, at the currently existing 24 GHz frequency (FIG. 6A), the data rate is limited to approximately 48 Gbps. However, the increase to approximately 29 GHz or 30 GHz allows for significant data rate increases up to approximately 112 Gbps. That is, the data rate can be more than doubled as a result of improved electrical shielding provided by channels disclosed herein.

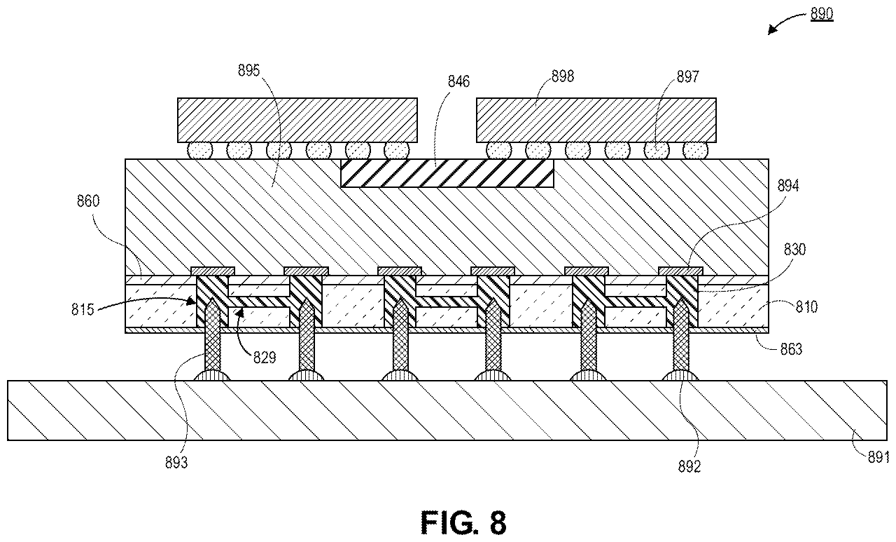

Referring now to FIG. 8, a cross-sectional illustration of an electronic system 890 is shown, in accordance with an embodiment. In an embodiment, the electronic system 890 may comprise a board 891, such as a printed circuit board (PCB). Pins 893 may be coupled to the board by electrically conductive solder 892 or other conductive mechanical coupling mechanism.

In an embodiment, a package substrate 895 may be coupled to the board 891 using a liquid metal approach. For example, pads 894 may be directly contacting liquid metal 830 that is provided in openings 815 through a liquid metal interposer 810. The liquid metal interposer 810 and the openings 815 may be similar to any liquid metal interposer or opening architecture described in greater detail herein. An adhesive 860 may secure the liquid metal interposer 810 to the package substrate 895. A capping layer 863 may be provided over the liquid metal interposer 810 to seal the openings 815. The pins 893 may pierce the capping layer 863, and the pins 893 directly contact the liquid metal 830.

In an embodiment channels 829 may be provided between neighboring pairs of openings 815. The channels 829 may be filled with the liquid metal 830 and allow for fluidically coupling neighboring channels. In an embodiment, the channels 829 may be embedded within a thickness of the liquid metal interposer 810. Further, a plurality of channels 829 may be provided between each pair of openings 815. The channels 829 may be similar to any of the channel architectures described herein.

In an embodiment, one or more dies 898 may be coupled to the package substrate 895 through interconnects 897, such as a first level interconnect (FLI) architecture. In an embodiment, two or more dies 898 may be communicatively coupled to each other through a bridge 896. The bridge 896 may be embedded in the package substrate 895 or provided above a surface of the package substrate 895. In an embodiment, the one or more dies 898 may be any type of die, such as a central processing unit (CPU), a graphics processing unit (GPU), an XPU, a system on a chip (SoC), a communications die, a memory die, or the like.

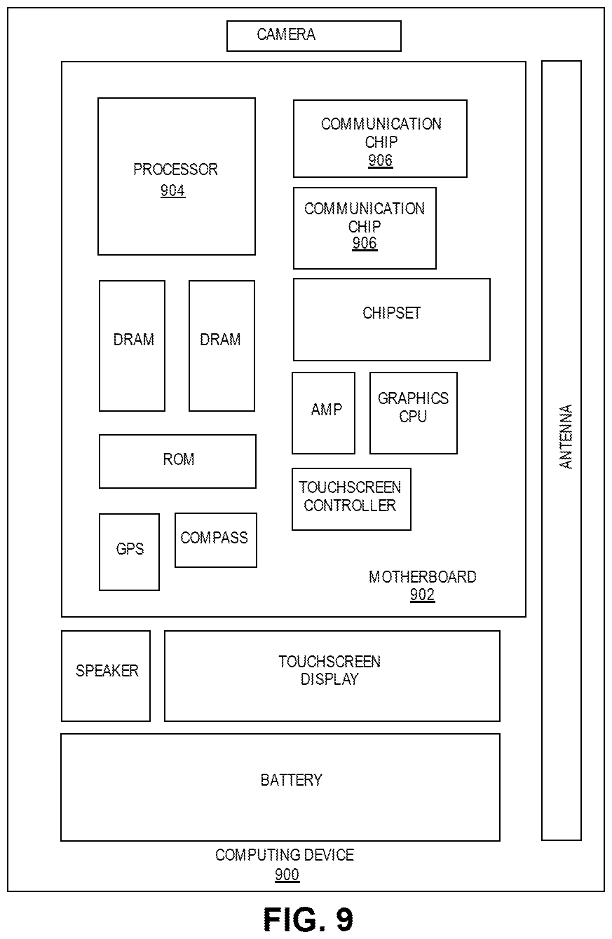

FIG. 9 illustrates a computing device 900 in accordance with one implementation of the invention. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor may be part of an electronic package that is coupled to a board through an injection molded liquid metal interposer with channels between openings in the liquid metal interposer, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the invention, the integrated circuit die of the communication chip may be part of electronic package that is coupled to a board through an injection molded liquid metal interposer with channels between the openings in the liquid metal interposer, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an apparatus, comprising: substrate; a first opening in the substrate; a second opening in the substrate; and a channel between the first opening and the second opening, wherein the channel fluidically couples the first opening to the second opening; wherein there is liquid metal in the first opening, the second opening, and the channel.

Example 2: the apparatus of Example 1, wherein the liquid metal comprises gallium

Example 3: the apparatus of Example 1 or Example 2, wherein the channel is between a top surface of the substrate and a bottom surface of the substrate.

Example 4: the apparatus of Examples 1-3, wherein the channel is at a top surface of the substrate.

Example 5: the apparatus of Examples 1-4, further comprising: a plurality of channels between the first opening and the second opening.

Example 6: the apparatus of Examples 1-5, wherein the substrate comprises a first half and a second half, wherein a seam is provided between the first half and the second half.

Example 7: the apparatus of Example 6, wherein the seam intersects the channel.

Example 8: the apparatus of Examples 1-7, wherein the openings have cross-sections that are circular or polygonal.

Example 9: the apparatus of Examples 1-8, wherein sidewalls of the openings are tapered.

Example 10: the apparatus of Examples 1-9, further comprising: a third opening; and a second channel between the second opening and the third opening, wherein the second channel fluidically couples the second opening to the third opening.

Example 11: an apparatus, comprising: a substrate; first openings through the substrate; and second openings through the substrate, wherein second openings are fluidically coupled to each other by channels embedded in the substrate, and wherein the first openings, second openings, and channels include liquid metal therein.

Example 12: the apparatus of Example 11, wherein a plurality of second openings are arranged around one or more first opening, and wherein the plurality of second openings are all fluidically coupled together by a plurality of channels.

Example 13: the apparatus of Example 12, wherein the first opening is configured to be a signal interconnect, and wherein the second openings are configured to be ground interconnects.

Example 14: the apparatus of Examples 11-13, wherein the liquid metal comprises gallium.

Example 15: the apparatus of Examples 11-14, wherein the first openings and the second openings have cross-sections that are circular or polygonal.

Example 16: the apparatus of Examples 11-15, wherein one or more of the second openings are connected to three or more channels.

Example 17: the apparatus of Examples 11-16, wherein two or more channels couple together individual pairs of second openings.

Example 18: an electronic system, comprising: a board; a package substrate coupled to the board by a socket architecture, wherein the socket architecture comprises: an interposer; a first opening in the interposer; a second opening in the interposer; a channel embedded in the interposer, wherein the channel fluidically couples the first opening to the second opening; a liquid metal in the first opening, the second opening, and the channel; a capping layer over the interposer to confine the liquid metal; and a pin extending from the board inserted through the capping layer; and a die coupled to the package substrate.

Example 19: the electronic system of Example 18, wherein the first opening and the second opening are configured for ground interconnects.

Example 20: the electronic system of Example 18 or Example 19, wherein the electronic system is part of a personal computer, a server, a mobile device, a tablet, or an automobile.

What is claimed is:

1. An apparatus, comprising:
a substrate;
a first opening in the substrate;
a second opening in the substrate; and
a channel between the first opening and the second opening, wherein the channel fluidically couples the first opening to the second opening;
wherein there is liquid metal in the first opening, the second opening, and the channel.

2. The apparatus of claim 1, wherein the liquid metal comprises gallium.

3. The apparatus of claim 1, wherein the channel is between a top surface of the substrate and a bottom surface of the substrate.

4. The apparatus of claim 1, wherein the channel is at a top surface of the substrate.

5. The apparatus of claim 1, further comprising:
a plurality of channels between the first opening and the second opening.

6. The apparatus of claim 1, wherein the substrate comprises a first half and a second half, wherein a seam is provided between the first half and the second half.

7. The apparatus of claim 6, wherein the seam intersects the channel.

8. The apparatus of claim 1, wherein the openings have cross-sections that are circular or polygonal.

9. The apparatus of claim 1, wherein sidewalls of the openings are tapered.

10. The apparatus of claim 1, further comprising:
a third opening; and
a second channel between the second opening and the third opening, wherein the second channel fluidically couples the second opening to the third opening.

11. An apparatus, comprising:
a substrate;
first openings through the substrate; and
second openings through the substrate, wherein the second openings are fluidically coupled to each other by channels embedded in the substrate, and wherein the first openings, second openings, and channels include liquid metal therein.

12. The apparatus of claim 11, wherein a plurality of second openings are arranged around one or more first opening, and wherein the plurality of second openings are all fluidically coupled together by a plurality of channels.

13. The apparatus of claim 12, wherein the first opening is configured to be a signal interconnect, and wherein the second openings are configured to be ground interconnects.

14. The apparatus of claim 11, wherein the liquid metal comprises gallium.

15. The apparatus of claim 11, wherein the first openings and the second openings have cross-sections that are circular or polygonal.

16. The apparatus of claim 11, wherein one or more of the second openings are connected to three or more channels.

17. The apparatus of claim 11, wherein two or more channels couple together individual pairs of second openings.

18. An electronic system, comprising:
a board;
a package substrate coupled to the board by a socket architecture, wherein the socket architecture comprises:
an interposer;
a first opening in the interposer;
a second opening in the interposer;
a channel embedded in the interposer, wherein the channel fluidically couples the first opening to the second opening;
a liquid metal in the first opening, the second opening, and the channel;
a capping layer over the interposer to confine the liquid metal; and
a pin extending from the board inserted through the capping layer; and
a die coupled to the package substrate.

19. The electronic system of claim 18, wherein the first opening and the second opening are configured for ground interconnects.

20. The electronic system of claim 18, wherein the electronic system is part of a personal computer, a server, a mobile device, a tablet, or an automobile.
